(19) United States
(12) Patent Application Publication
(10) Pub. No.: US 2008/0042722 A1
(43) Pub. Date: Feb. 21, 2008

(54) High speed level shifter circuit and circuit using same

(75) Inventor: Andrew W. Dornbusch, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: SILICON LABORATORIES, INC., Austin, TX (US)

(21) Appl. No.: 11/504,441

(22) Filed: Aug. 15, 2006

(51) Int. Cl. H03L 5/00

(52) U.S. Cl. 327/333

(57) ABSTRACT

A level shifter (320) includes a first capacitor (510/612/712), a first resistor (524/626/734), a first switch (526/630/728), and a first current source (528/632/730). The first capacitor has a first terminal for receiving an input signal, and a second terminal coupled to a first output terminal. The first resistor has a first terminal coupled to a first reference voltage terminal, and a second terminal coupled to the first output terminal. The first switch has a first current conducting electrode coupled to the second terminal of the first resistor, a control electrode for receiving a complement of the input signal, and a second current conducting electrode. The current source has a first terminal coupled to the second current conducting electrode of the first switch, and a second terminal coupled to a second reference voltage terminal. The level shifter (320) may be coupled between a phase detector (310) and a charge pump (330) of a phase locked loop (300).

### FIELD OF THE DISCLOSURE

This disclosure generally relates to voltage conversion circuits, and more particularly, to level shifter circuits and circuits using such level shifter circuits.

### BACKGROUND

Recent advances in complementary metal oxide semiconductor (CMOS) integrated circuit process technology have enabled CMOS transistors to switch at speeds in the gigahertz (GHz) range. These advances have opened up new applications for CMOS circuits in the field of signal transmission and reception. For example, Richard A. Johnson in U.S. Pat. No. 6,778,117 discloses a television receiver that is easily implemented on a CMOS integrated circuit chip. In this receiver, a very high-speed clock operating at 2 gigahertz (GHz) is used to generate clocking signals for on-chip components such as a digital-to-analog converter.

In order to generate an on-chip clock signal at 2 GHz or higher, known approaches use an on-chip phase locked loop (PLL) to multiply the frequency of a lower-speed off chip reference clock up to the desired frequency. However in CMOS circuits power consumption increases linearly with speed. Thus the PLL itself can significantly increase chip power consumption. Recent CMOS processes have also allowed operation at lower power supply voltages than before, such as 1.2 volts. The lower power supply voltages will reduce switching power consumption. However phase locked loop charge pumps do not operate well at low voltages because they require greater voltage headroom.

To solve the headroom problem while maintaining low power consumption, it is possible to operate most blocks of the PLL using a low power supply voltage, and translate the input logic signals of the charge pump to logic signals referenced to a higher power supply voltage. Then the charge pump alone can be operated at the higher power supply voltage while the other blocks of the PLL are operated at the lower power supply voltage. Unfortunately known level shifters do not operate well at high frequencies, distorting the short correction pulses that keep the output clock locked to the reference clock. These distorted correction pulses cause unacceptable clock jitter at the output of the PLL.

Thus known PLLs either operate at low power consumption but produce a clock with significant clock jitter, or produce a clock with acceptable clock jitter but consume a significant amount of power caused by operating at higher power supply voltages. It would be desirable to alleviate this inherent tradeoff between power consumption and clock jitter to better utilize the full benefits of available CMOS processes.

### SUMMARY

In one form, a level shifter includes a first capacitor, a first resistor, a first switch, and a first current source. The first capacitor has a first terminal for receiving an input signal, and a second terminal coupled to a first output terminal. The first resistor has a first terminal coupled to a first reference voltage terminal, and a second terminal coupled to the first output terminal. The first switch has a first current conducting electrode coupled to the second terminal of the first resistor, a control electrode for receiving a complement of the input signal, and a second current conducting electrode. The current source has a first terminal coupled to the second current conducting electrode of the first switch, and a second terminal coupled to a second reference voltage terminal.

In another form, a level shifter circuit includes an input node for receiving an input signal having logic voltage levels referenced to a first power domain, an output node for providing an output signal having logic voltage levels referenced to a second power domain, a high frequency path circuit, and a low frequency path circuit. The high frequency path circuit has an input terminal coupled to the input node, and an output terminal coupled to the output node for altering a voltage on the output node in response to high frequency components of the input signal. The low frequency path circuit has an input terminal coupled to the input node and an output terminal coupled to the output node, the low frequency path circuit forms output high and output low logic levels referenced to the second power domain on the output node in response to the input signal.

In yet another form, a circuit has a level shifter integral therewith. The level shifter includes a first capacitor, a first resistor, a first switch, and a first current source. The first capacitor has a first terminal for receiving an input signal, and a second terminal coupled to a first output terminal. The first resistor has a first terminal coupled to a first reference voltage terminal, and a second terminal coupled to the first output terminal. The first switch has a first current conducting electrode coupled to the second terminal of the first resistor, a control electrode for receiving a complement of the input signal, and a second current conducting electrode. The current source has a first terminal coupled to the second current conducting electrode of the first switch, and a second terminal coupled to a second reference voltage terminal.

In one particular embodiment, the circuit includes a phase detector, a charge pump, a loop filter, a voltage controlled oscillator, and a frequency divider. The phase detector has a first input for receiving a reference clock, a second input, and an output for providing the input signal to the level shifter circuit. The charge pump has an input coupled to the first output terminal of the level shifter circuit, and an output. The loop filter has an input coupled to the output of the charge pump, and an output. The voltage controlled oscillator has an input coupled to the output of the loop filter, and an output for providing an output clock signal. The frequency divider has an input coupled to the output of the voltage controlled oscillator, and an output coupled to the second input of the phase detector.

### BRIEF DESCRIPTION OF THE DRAWINGS

The present disclosure may be better understood, and its numerous features and advantages made apparent to those skilled in the art by referencing the accompanying drawings.

FIG. 1 illustrates in block diagram form a phase locked loop known in the prior art;

FIG. 2 illustrates in schematic form a charge pump circuit known in the prior art suitable for use in the phase locked loop of FIG. 1;

FIG. 3 illustrates in block diagram form a phase locked loop with a level shifter according to the present invention;

FIG. 4 illustrates in partial logic diagram and partial schematic form a level shifter known in the prior art;

FIG. 5 illustrates in partial logic diagram and partial schematic form a level shifter according to one embodiment of the present invention;

FIG. 6 illustrates in schematic form a level shifter according to another embodiment of the present invention suitable for use in the phase locked loop of FIG. 1;

FIG. 7 illustrates in schematic form a level shifter according to yet another embodiment of the present invention.

### DETAILED DESCRIPTION

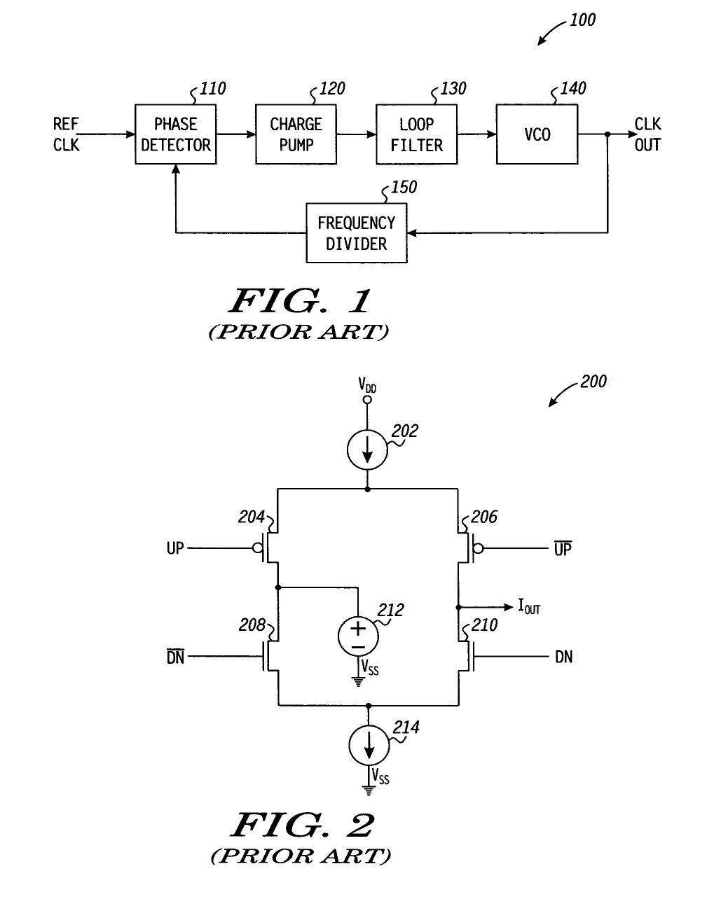

FIG. 1 illustrates in block diagram form a phase locked loop (PLL) 100 known in the prior art. PLL 100 includes generally a phase detector 110, a charge pump 120, a level sifter 130, a voltage controlled oscillator (VCO) 140, and a frequency divider 150. Phase detector 110 has a first input for receiving a reference clock signal labeled “REF CLK”, a second input, and an output. Charge pump 120 has an input connected to the output of phase detector 110, and an output. Loop filter 130 has an input connected to the output of charge pump 120, and an output. VCO 140 has an input connected to the output of loop filter 130, and an output for providing an output clock signal labeled “CLK OUT”. Frequency divider 150 has an input connected to the output of VCO 140, and an output connected to the second input of phase detector 110.

PLL 100 is a conventional phase locked loop that can be used to produce CLK OUT at a higher frequency than REF CLK. Phase detector 110 detects a difference in frequency (or phase) between the REF CLK and a divided-down version of CLK OUT. In response to detecting such a difference, phase detector 110 directs charge pump 120 to increase the frequency (such as by way of an up or “UP” signal) or decrease the frequency (such as by way of a down or “DN” signal). Charge pump 120 is responsive to the UP and DN signals to provide a positive or negative current to or from, respectively, loop filter 130. VCO 140 provides CLK OUT at a frequency proportional to the voltage stored by loop filter 130.

Modern CMOS integrated circuits are capable of operating at frequencies in the gigahertz (GHz) range, and REF CLK can be in the range of tens of megahertz (MHz). Accordingly, the power consumed by PLL 100, which in CMOS circuits is proportional to speed, can be quite large. In order to reduce the power consumption, it is desirable to use low power supply voltage CMOS circuitry.

At the same time, after PLL 100 achieves lock, small deviations in the output frequency will cause phase detector 110 to produce very narrow correction pulses (UP or DN). Since these narrow pulses contain high frequency harmonic components, it is necessary for charge pump 120 to transition very quickly and linearly. FIG. 2 illustrates in schematic form a charge pump circuit 200 known in the prior art suitable for use in PLL 100 of FIG. 1. Charge pump 200 includes a current source 202, P-channel MOS transistors 204 and 206, N-channel MOS transistors 208 and 210, a voltage source 212, and a current source 214. Current source 202 has a first terminal connected to a more positive power supply voltage labeled “V_{DD}”, and a second terminal. Transistor 204 has a source connected to the second terminal of current source 202, a gate for receiving the UP signal, and a drain. Transistor 206 has a source connected to the second terminal of current source 202, a gate for receiving a complement of the UP signal labeled “ U̅P̅”, and a drain for providing an output current signals labeled “I_{OUT}”. Transistor 208 has a drain connected to the drain of transistor 204, a gate for receiving a complement of the DN signal labeled “ D̅N̅”, and a source. Transistor 210 has a drain connected to the drain of transistor 206, a gate for receiving the DN signal, and a source. Voltage source 212 has a positive terminal connected to the drains of transistors 204 and 208, and a negative terminal connected to a more negative or ground power supply voltage terminal labeled “V_{SS}”. Current source 214 has a first terminal connected to the sources of transistors 208 and 210, and second terminal connected to V_{SS}.

Charge pump 200 is a current-steering charge pump that selectively diverts current conducted by current source 202 and current conducted by current source 214. In response to an up pulse (UP is at a logic high and U̅P̅ is at a logic low, while DN is at a logic low and D̅N̅ is at a logic high), transistors 204 and 210 are nonconductive, and transistors 206 and 208 are conductive, providing a positive current I_{OUT}, i.e. providing current into the loop filter. In response to a down pulse (DN is at a logic high and D̅N̅ is at a logic low, while UP is at a logic low and U̅P̅ is at a logic high), transistors 204 and 210 are conductive, and transistors 206 and 208 are nonconductive, providing a negative current I_{OUT}, i.e. drawing current from the loop filter.

Because it has four stacked devices connected between V_{DD} and V_{SS}, including current sources 202 and 214, charge pump 200 requires a relatively large value of V_{DD} to provide sufficient headroom for current sources 202 and 214. For example, charge pump 200 may require a minimum V_{DD} of 3.0 volts, whereas a digital logic circuit using the same manufacturing process may only require a V_{DD} to be 1.2 volts.

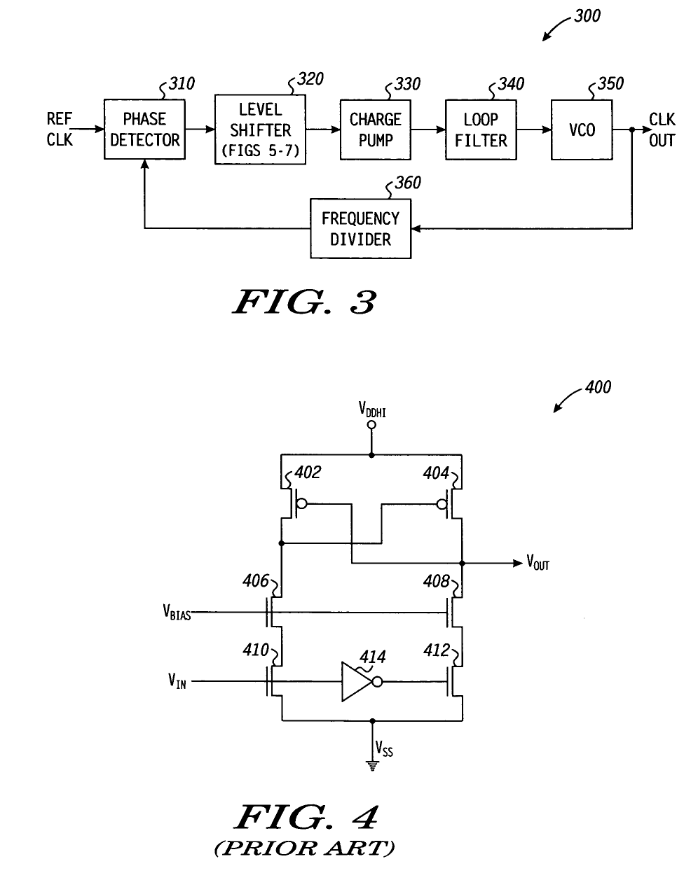

Returning to FIG. 1, in order to reduce power consumption, it is possible to implement all blocks of PLL 100, except for charge pump 200, with low voltage logic, and then to translate the low voltage logic signals to logic signals referenced to the higher supply voltage to drive charge pump 200. FIG. 3 illustrates in block diagram form a phase locked loop (PLL) 300 with a level shifter 320 according to the present invention. PLL 300 includes generally a phase detector 310, level shifter 320, a charge pump 330, a loop filter 340, a VCO 350, and a frequency divider 360. Phase detector 310 has a first input for receiving reference clock signal REF CLK, a second input, and an output. Level shifter 320 has an input connected to the output of phase detector 310, and an output. Charge pump 330 has an input connected to the output of level shifter 320, and an output. Loop filter 340 has an input connected to the output of charge pump 330, and an output. VCO 350 has an input connected to the output of loop filter 340, and an output for providing output clock signal CLK OUT. Frequency divider 360 has an input connected to the output of VCO 350, and an output connected to the second input of phase detector 310.

PLL 300 uses a relatively low power supply voltage designated “V_{DDLO}” to supply phase detector 310, VCO 350, and frequency divider 360, but uses a relatively high power supply voltage designated “V_{DDHI}” to supply charge pump 330. In one particular example, V_{DDLO} is 1.2 volts while V_{DDHI} is 3.0 volts. In accordance with the present invention, PLL 300 maintains low power consumption while preserving the benefits of a wide headroom charge pump such as charge pump 200 of FIG. 2. PLL 300 uses level shifter 320 to translate between logic signals referenced to V_{DDLO} provided by phase detector 310 and logic signals referenced to V_{DDHI} needed by charge pump 330. Unlike known level shifters, level shifter 320 is capable of preserving the high frequency content of the short duration correction pulses often encountered in phase locked loops once they have achieved lock.

To understand the operation of level shifter 320, it is helpful to understand the operation and deficiencies of known level shifters. FIG. 4 illustrates in partial logic diagram and partial schematic form a level shifter 400 known in the prior art. Level shifter 400 includes P-channel MOS transistors 402 and 404, N-channel transistors 406, 408, 410, and 412, and an inverter 414. Transistor 402 has a source connected to V_{DDHI}, a gate, and a drain. Transistor 404 has a source connected to V_{DDHI}, a gate connected to the drain of transistor 402, and a drain connected to the gate of transistor 402 and providing a signal labeled “V_{OUT}” thereon. Transistor 406 has a drain connected to the drain of transistor 402, a gate for receiving a bias voltage labeled “V_{BIAS}”, and a source. Transistor 408 has a drain connected to the drain of transistor 404, a gate for receiving bias voltage V_{BIAS}, and a source. Transistor 410 has a drain connected to the source of transistor 406, a gate for receiving an input voltage labeled “V_{IN}”, and a source connected to V_{SS}. Transistor 412 has a drain connected to the source of transistor 408, a gate, and a source connected to V_{SS}. Inverter 414 has an input terminal for receiving V_{IN}, and an output terminal connected to the gate of transistor 412.

In operation, level shifter 400 is biased between the higher power supply voltage V_{DDHI} and V_{SS}. Transistors 406 and 408 are cascode-connected transistors provided to keep the full value of V_{DDHI} from appearing at the drains of transistors 410 and 412. If V_{IN} is a logic high, transistor 410 is conductive and transistor 412 is nonconductive. The voltage at the drain of transistor 402 falls, causing transistor 404 to become conductive. As transistor 404 becomes conductive, the voltage at the drain thereof (voltage V_{OUT}) rises toward V_{DDHI}, which in turn makes transistor 402 nonconductive. Once transistor 402 has been rendered nonconductive, transistors 406 and 410 pull the drain of transistor 402 to approximately the voltage of V_{SS}, or approximately zero volts. Similarly if V_{IN} is a logic low, transistor 412 is conductive and transistor 410 is nonconductive. The voltage at the drain of transistor 404 falls, causing transistor 402 to become conductive. As transistor 402 becomes conductive, the voltage at the drain thereof rises toward V_{DDHI}, which in turn makes transistor 404 nonconductive. Once transistor 404 has been rendered nonconductive, transistors 408 and 412 pull the drain of transistor 404 to approximately the voltage of V_{SS}, or approximately zero volts. Thus level shifter 400 provides V_{OUT} with a rail-to-rail logic swing between approximately zero volts and V_{DDHI}.

Four level shifters constructed identically to level shifter 400 could be used in PLL 300 to produce level shifted versions of signals UP, U̅P̅, DN, and D̅N̅ to charge pump 330. However there are several practical problems with this approach.

First, MOS transistors (such as transistors 204, 206, 208, and 210 in charge pump 200) have significant parasitic gate capacitance. Driving charge pump 200 with logic signals referenced to a higher power supply voltage would cause significantly increased charge injection into the charge pump through repetitive charging and discharging of the parasitic gate capacitances.

Second, fine control over precise switching times necessary to keep clock jitter low is impractical. The actual transition voltages for the various current-steering transistors are dependent on their quiescent voltage, which varies from transistor to transistor.

Third, level shifter 400 itself consumes a significant amount of power.

Fourth, level shifter 400 is designed to transfer one single-ended signal instead of a logically-related differential pair. Any device mismatch between two separate level shifters, although identically constructed, would add mismatch between the output waveforms in timing or edge rate, causing clock jitter.

Fifth, level shifter 400 does not have balanced outputs. The positive and negative slew rates are difficult to match.

Sixth, the actual signal swing needed to switch the charge-pump current steering devices is typically considerably less than its supply rail. For example, the supply voltage can exceed 3.0 volts but the switching voltage may be less than 1.0 volts. Moreover this switching voltage must be centered at a voltage somewhere between the supplies. However charge pump 400 switches rail to rail.

Level shifter 320 overcomes these problems. A circuit such as a PLL using level shifter 320 consumes a small amount of power while providing high bandwidth, resulting in very low clock jitter. More particularly both the desired amount of output signal swing and the voltage at which this signal swing is centered can be selected as desired.

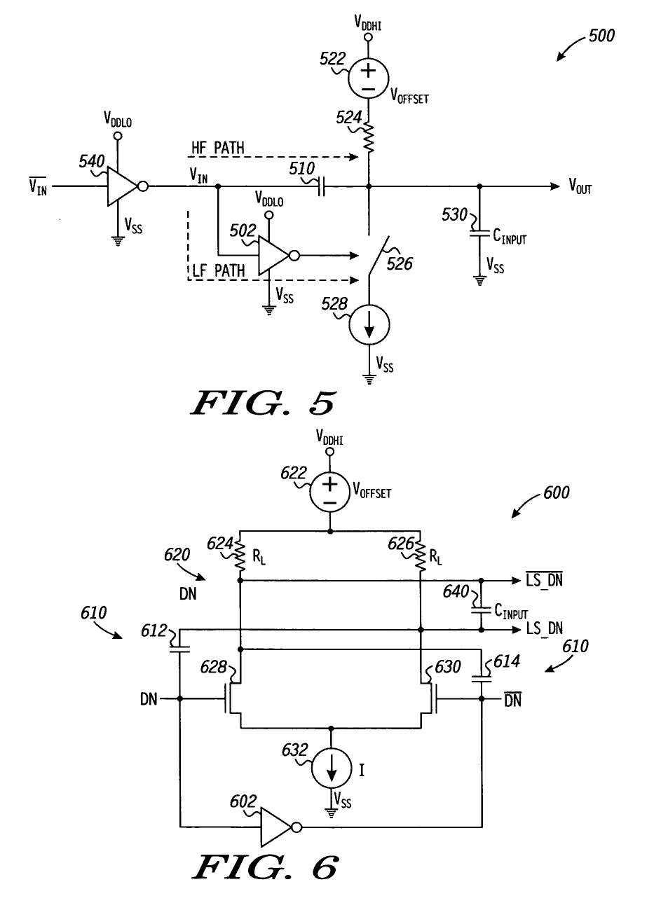

FIGS. 5-7 illustrate different embodiments of level shifter 320. FIG. 5 illustrates in partial logic diagram and partial schematic form a level shifter 500 according to one embodiment of the present invention. Level shifter 500 is a single-ended level shifter that would be suitable for use with a single-ended charge pump. Level shifter 500 includes an inverter 502, a capacitor 510, a voltage source 522, a resistor 524, a switch 526, and a current source 528. Inverter 502 has an input terminal for receiving input signal V_{IN} at an input node, an output terminal, a positive power supply terminal for receiving V_{DDLO}, and a negative power supply terminal for receiving V_{SS}. Capacitor 510 has a first terminal connected to the input node, and a second terminal connected to an output node that provides voltage V_{OUT} thereon. Voltage source 522 has a positive terminal for receiving V_{DDHI}, and a negative terminal, and has a voltage drop labeled “V_{OFFSET}” associated therewith. Resistor 524 has a first terminal connected to the negative terminal of voltage source 522, and a second terminal connected to the second terminal of capacitor 510 at the output node. Switch 526 has a first current conducting terminal connected to the second terminals of capacitor 510 and resistor 524, a second current conducting terminal, and a control terminal connected to the output terminal of inverter 502. Current source 528 has a first terminal connected to the second current conducting terminal of switch 526, and a second terminal connected to V_{SS}.

Also shown in FIG. 5 are a capacitor 530 and an inverter 540. Capacitor 530 has a first terminal connected to the output node, and a second terminal connected to V_{SS}, and represents the input capacitance of charge pump 330, labeled “C_{INPUT}”. Inverter 540 represents low voltage circuitry in phase detector 310 that provides V_{IN} as a logic signal referenced to the V_{DDLO} domain. Inverter 540 has an input terminal for receiving a complement of V_{IN} labeled “ V̅_̅{̅I̅N̅}̅”, an output terminal connected to the first terminal of capacitor 510 and to the input terminal of inverter 502, a positive power supply input terminal for receiving V_{DDLO}, and a negative power supply terminal for receiving V_{SS}.

Level shifter 500 includes two separate paths: a high frequency path labeled “HF PATH” through a high frequency path circuit including capacitor 510, and a low frequency path labeled “LF path” through a low frequency path circuit including inverter 502, voltage source 522, resistor 524, switch 526, and current source 528. The high frequency path circuit alters V_{OUT} in response to high frequency components of V_{IN}. Since capacitor 510 is a short circuit at high frequencies, it conducts short up and down pulses at the output phase detector 310 directly to V_{OUT}. Thus the high frequency path circuit preserves the responsiveness of PLL 300 to slight variations in phase and/or frequency of CLK OUT that are important for maintaining low clock jitter.

The low frequency path circuit forms output high and output low logic levels referenced to the V_{DDHI} power domain on the V_{OUT} node in response to V_{IN}. Alternatively, the low frequency path circuit can be conceived of as a biasing circuit that maintains proper bias across capacitor 510. When switch 526 is open, the low frequency path circuit forms the output logic level as a logic high voltage equal to V_{DDHI}−V_{OFFSET}. When switch 526 is closed, the low frequency path circuit forms the output logic level as a logic low equal to V_{DDHI}−V_{OFFSET}−I₅₂₈R₅₂₄, wherein I₅₂₈ is the current of current source 528, and R₅₂₄ is the resistance of resistor 524. Thus the voltage offset of voltage source 522, the resistance of resistor 524, and the current of current source 528 can be varied to provide the proper logic swing centered at the desired voltage. The output signal doesn't have to switch rail to rail but only in the amount necessary to switch the corresponding transistors in the charge pump/Moreover, resistor 524 can desirably be made large to reduce power consumption.

FIG. 6 illustrates in schematic form a level shifter 600 according to another embodiment of the present invention suitable for use in PLL 300 of FIG. 3. Level shifter 600 is a differential level shifter that would be suitable for use with a differential charge pump. Level shifter 600 includes an inverter 602, a high frequency path circuit 610, and a low frequency path circuit 620. Inverter 602 has an input terminal for receiving voltage DN, and an output terminal for providing voltage D̅N̅.

High frequency path circuit 610 includes generally capacitors 612 and 614. Capacitor 612 has a first terminal for receiving DN, and a second terminal for providing an output labeled “LS_DN”. Capacitor 614 has a first terminal for receiving D̅N̅, and a second terminal for providing an output labeled “ L̅S̅_̅D̅N̅”.

Low frequency path circuit 620 includes a voltage source 622, resistors 624 and 626, N-channel MOS transistors 628 and 630, and a current source 632. Voltage source 622 has a positive terminal connected to V_{DDHI}, and a negative terminal, and has a voltage drop V_{OFFSET} associated therewith. Resistor 624 has a first terminal connected to the negative terminal of voltage source 622, and a second terminal connected to the second terminal of capacitor 614, and has a resistance labeled “R_{L}” associated therewith. Resistor 626 has a first terminal connected to the negative terminal of voltage source 622, and a second terminal connected to the second terminal of capacitor 612, and has resistance R_{L} associated therewith. Transistor 628 has a drain connected to the second terminal of resistor 624, a gate for receiving signal DN, and a source. Transistor 630 has a drain connected to the second terminal of resistor 626, a gate for receiving signal D̅N̅, and a source. Current source 632 has a first terminal connected to the sources of transistors 628 and 630, and a second terminal connected to V_{SS}.

Also shown in FIG. 6 is a capacitor 640. Capacitor 640 has a first terminal connected to the second terminal of resistor 624, and a second terminal connected to the second terminal of resistor 626, and has capacitance C_{INPUT} associated therewith that represents the differential input capacitance of charge pump 330.

Level shifter 600 efficiently implements a differential level shifter since current source 632 and inverter 602 can be reused. Transistors 628 and 630 operate as current steering devices, which feed biasing current I₆₃₂ through either resistor 624 or resistor 626. High frequency circuit 610 provides the high frequency content of the DN and D̅N̅ signals directly to LS_DN and L̅S̅_̅D̅N̅ since capacitors 612 and 614 become short circuits at high frequencies. Low frequency circuit 620 maintains proper bias on the second terminals of capacitors 612 and 614. The quiescent output high voltage of the level shifter 600 is equal to V_{DDHI}−V_{OFFSET} and can be set as appropriate to correctly bias transistors 628 and 630. The magnitudes of I and R_{L} must be set so that the product IR_{L} approximates the swing of the DN and D̅N̅ signals.

Note that the magnitude of the output signals swing does not need to be as large as the swing of DN and D̅N̅. Rather it can be reduced by ratioing the size of bypass capacitors 612 and 614 relative to the parasitic input capacitance C_{INPUT} of the charge pump switches, with the potential across the R_{L} resistors reduced accordingly. This enables the control signal to be reduced to the minimum level necessary to operate the charge pump switches, which minimizes charge pump feedthrough currents.

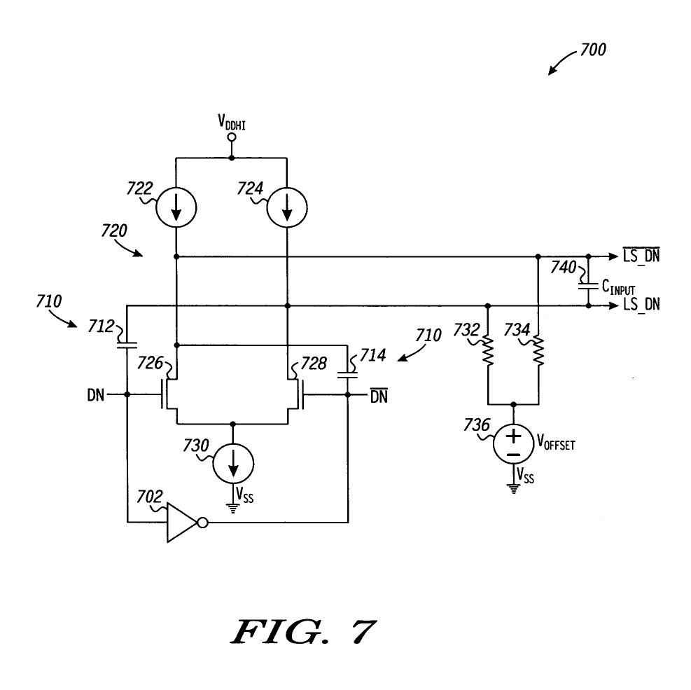

FIG. 7 illustrates in schematic form a level shifter 700 according to yet another embodiment of the present invention. Level shifter 700 includes an inverter 702, a high frequency portion 710, and a low frequency portion 720. Inverter 702 has an input terminal for receiving voltage DN, and an output terminal for providing voltage D̅N̅.

High frequency portion 710 includes generally capacitors 712 and 714. Capacitor 712 has a first input terminal for receiving DN, and a second terminal for providing output LS_DN. Capacitor 714 has a first input terminal for receiving D̅N̅, and a second terminal for providing output L̅S̅_̅D̅N̅.

Low frequency portion 720 includes a current source 722, a current source 724, N-channel MOS transistors 726 and 728, a current source 730, resistors 732 and 734, and a voltage source 736. Current source 722 has a first terminal connected to V_{DDHI}, and a second terminal connected to the second terminal of capacitor 714. Current source 724 has a first terminal connected to V_{DDHI}, and a second terminal connected to the second terminal of capacitor 712. Transistor 726 has a drain connected to the second terminal of current source 722, a gate for receiving signal DN, and a source. Transistor 630 has a drain connected to the second terminal of current source 724, a gate for receiving signal D̅N̅, and a source. Current source 730 has a first terminal connected to the sources of transistors 726 and 728, and a second terminal connected to V_{SS}. Resistor 732 has a first terminal, and a second terminal connected to the drain of transistor 726 for providing signal L̅S̅_̅D̅N̅. Resistor 734 has a first terminal, and a second terminal connected to the drain of transistor 728 for providing signal LS_DN. Voltage source 736 has a positive terminal connected to the first terminals of resistors 732 and 734, a negative terminal connected to V_{SS}, and has an associated voltage V_{OFFSET}.

Also shown in FIG. 7 is a capacitor 740. Capacitor 740 has a first terminal connected to the second terminals of current source 722 and resistor 732, and a second terminal connected to the second terminals of current source 724 and resistor 734, and has capacitance C_{INPUT} associated therewith that represents the differential input capacitance of charge pump 330.

Level shifter 700 is similar to level shifter 600 of FIG. 6 except that it employs a folded pullup scheme. Thus level shifter 700 is suitable for operation in systems in which the level-shifted output voltages are smaller than those of FIG. 6 such that the headroom of transistors 628 and 630 and current source 632 of level shifter 600 would otherwise not be sufficient.

It should be apparent that other level shifters having both a high frequency path circuit and a low frequency path circuit can be constructed according to the principles described herein. Moreover both single-ended (level shifter 500) and differential (level shifter 600) versions can be constructed as needed. As well as a folded version (level shifter 700).

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A level shifter circuit comprising:
a first capacitor having a first terminal for receiving an input signal, and a second terminal coupled to a first output terminal;
a first resistor having a first terminal coupled to a first reference voltage terminal, and a second terminal coupled to said first output terminal;
a first switch having a first current conducting electrode coupled to said second terminal of said first resistor, a control electrode for receiving a complement of said input signal, and a second current conducting electrode; and
a current source having a first terminal coupled to said second current conducting electrode of said first switch, and a second terminal coupled to a second reference voltage terminal.

2. The level shifter circuit of claim 1 further comprising:
an inverter having an input terminal for receiving said input signal, and an output terminal coupled to said control electrode of said first switch for providing said complement of said input signal.

3. The level shifter circuit of claim 1 further comprising:
a voltage source having a first terminal coupled to a first power supply voltage terminal, and a second terminal coupled to said first reference voltage terminal.

4. The level shifter circuit of claim 1 wherein said first switch comprises a metal oxide semiconductor (MOS) field effect transistor.

5. The level shifter circuit of claim 1 further comprising:
a second capacitor having a first terminal for receiving said complement of said input signal, and a second terminal coupled to a second output terminal;
a second resistor having a first terminal coupled to said first reference voltage terminal, and a second terminal coupled to said second output terminal; and
a second switch having a first current conducting electrode coupled to said second terminal of said second resistor, a second current conducting electrode coupled to said first terminal of said current source, and a control electrode for receiving said input signal.

6. The level shifter circuit of claim 5 wherein said first and second switches comprise metal oxide semiconductor (MOS) field effect transistors.

7. The level shifter circuit of claim 5 wherein capacitances of said first capacitor and said second capacitor are each approximately equal to a parasitic capacitance between said first and second output terminals, thereby attenuating said input signal.

8. A level shifter circuit comprising:
an input node for receiving an input signal having logic voltage levels referenced to a first power domain;
an output node for providing an output signal having logic voltage levels referenced to a second power domain;
a high frequency path circuit having an input terminal coupled to said input node, and an output terminal coupled to said output node for altering a voltage on said output node in response to high frequency components of said input signal; and
a low frequency path circuit having an input terminal coupled to said input node and an output terminal coupled to said output node, said low frequency path circuit forming output high and output low logic levels referenced to said second power domain on said output node in response to said input signal.

9. The level shifter circuit of claim 8, wherein said high frequency path circuit comprises a capacitor.

10. The level shifter circuit of claim 8, wherein said low frequency path circuit is characterized as being a differential circuit.

11. The level shifter circuit of claim 10, wherein said low frequency path circuit is characterized as being a folded differential circuit.

12. The level shifter circuit of claim 8, wherein said low frequency path circuit comprises:
a first resistor having a first terminal coupled to a first reference voltage terminal, and a second terminal coupled to said first output terminal;
a first switch having a first current conducting electrode coupled to said second terminal of said first resistor, a control electrode for receiving a complement of said input signal, and a second current conducting electrode; and
a current source having a first terminal coupled to said second current conducting electrode of said first switch, and a second terminal coupled to a second reference voltage terminal.

13. A circuit having a level shifter circuit integral therewith, the level shifter circuit comprising:
a first capacitor having a first terminal for receiving an input signal, and a second terminal coupled to a first output terminal;
a first resistor having a first terminal coupled to a first reference voltage terminal, and a second terminal coupled to said first output terminal;
a first switch having a first current conducting electrode coupled to said second terminal of said first resistor, a control electrode for receiving a complement of said input signal, and a second current conducting electrode; and
a current source having a first terminal coupled to said second current conducting electrode of said first switch, and a second terminal coupled to a second reference voltage terminal.

14. The circuit of claim 13 further comprising:
a phase detector having a first input for receiving a reference clock, a second input, and an output for providing said input signal to the level shifter circuit;
a charge pump having an input coupled to said first output terminal of the level shifter circuit, and an output;
a loop filter having an input coupled to said output of said charge pump, and an output;
a voltage controlled oscillator having an input coupled to said output of said loop filter, and an output for providing an output clock signal; and
a frequency divider having an input coupled to said output of said voltage controlled oscillator, and an output coupled to said second input of said phase detector.

15. The circuit of claim 14, wherein said phase detector operates in a first power domain, and said charge pump operates in a second power domain, said second power domain characterized as having a larger voltage swing than said first power domain.

16. The circuit of claim 14, wherein the level shifter circuit further comprises:
an inverter having an input terminal for receiving said input signal, and an output terminal coupled to said control electrode of said first switch for providing said complement of said input signal.

17. The circuit of claim 14, wherein the level shifter circuit further comprises:
a voltage source having a first terminal coupled to a first power supply voltage terminal, and a second terminal coupled to said first reference voltage terminal.

18. The circuit of claim 14, wherein said first switch comprises a metal oxide semiconductor (MOS) field effect transistor.

19. The circuit of claim 14, wherein the level shifter circuit further comprises:
a second capacitor having a first terminal for receiving said complement of said input signal, and a second terminal coupled to a second output terminal;
a second resistor having a first terminal coupled to said first reference voltage terminal, and a second terminal coupled to said second output terminal; and
a second switch having a first current conducting electrode coupled to said second terminal of said second resistor, a second current conducting electrode coupled to said first terminal of said current source, and a control electrode for receiving said input signal.

20. The circuit of claim 19, wherein said first and second switches comprise metal oxide semiconductor (MOS) field effect transistors.
